(19) United States
(12) Patent Application Publication
(10) Pub. No.: US 2012/0212236 A1
(43) Pub. Date: Aug. 23, 2012

(54) TESTING DEVICE FOR COMPUTER CONNECTOR

(75) Inventors: TENG-TSUNG HUANG, Tu-Cheng (TW); YONG-BING HU, Shenzhen City (CN); YUAN-ZHAO LI, Shenzhen City (CN); ZHAN SHANG, Shenzhen City (CN)

(73) Assignees: Hon Hai Precision Industry Co., Ltd., Tu-Cheng (TW); Hong Fu Jin Precision Industry (Shenzhen) Co., Ltd., Shenzhen City (CN)

(21) Appl. No.: 13/327,412

(22) Filed: Dec. 15, 2011

(30) Foreign Application Priority Data
Feb. 21, 2011 (CN) 201110041475.1

(51) Int. Cl. G01R 31/04

(52) U.S. Cl. 324/555

(57) ABSTRACT

A testing device is used to test the life of a connector of an electronic device. An external connector is plugged into the connector. The testing device includes a base, a fixing assembly for fixing the electronic device on the base, a driver, a pressing head driven by the driver and an adjusting assembly. The adjusting assembly is configured to adjust the position of the driver and the pressing head to align the pressing head with the external connector.

### BACKGROUND

1. Technical Field

The present disclosure generally relates to testing devices, particularly to a testing device for testing computer connector durability.

2. Description of Related Art

A typical electronic device usually includes many types of connectors, such as earphone connectors (jacks), universal serial bus (USB) connectors, etc. The connectors may be damaged if too much force is used to insert a plug or insertion is done at the wrong angle. Thus, the durability of connector needs to be tested, to ensure that damage will not occur too easily. Some devices used to test durability may include an air cylinder and a pressing head driven by the air cylinder. The air cylinder drives the pressing head to repeatedly strike or press against a plug inserted in the jack being tested a number of times at a predetermined pressure.

However, there are no adjustable universal test devices, so a different device is required for each different kind of device to be tested which is expensive and inconvenient.

Therefore, there is room for improvement within the art.

### BRIEF DESCRIPTION OF THE DRAWINGS

Many aspects of the disclosed testing device can be better understood with reference to the following drawings. The components in the drawings are not necessarily drawn to scale, the emphasis instead being placed upon clearly illustrating the principles of the present testing device.

FIG. 1 is a schematic view of an exemplary embodiment of a testing device in use testing an electronic device.

FIG. 2 is a schematic of the testing device of FIG. 1 without the electronic device.

FIG. 3 is an exploded view of the testing device of FIG. 2.

FIG. 4 is a schematic view of the testing device of FIG. 2 with a pressure setting assembly mounted thereon.

FIG. 5 is a schematic view of the testing device of FIG. 2 with a connecting element and a third pressing head mounted thereon.

FIG. 6 is a schematic view of another exemplary embodiment of a testing device.

FIG. 7 is a schematic view of the testing device of FIG. 6 in use testing an electronic device.

### DETAILED DESCRIPTION

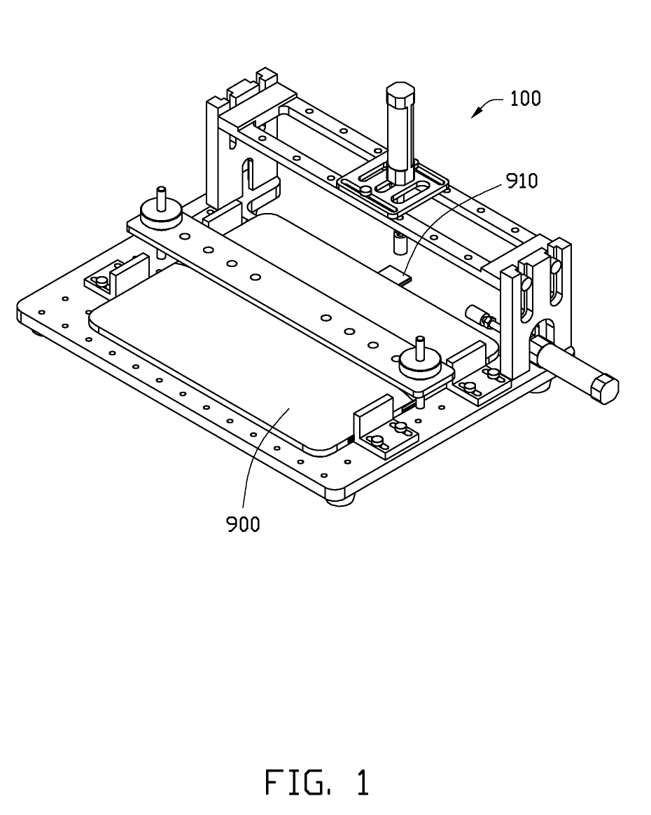

FIG. 1 shows an exemplary embodiment of a testing device 100 for testing connector durability of an electronic device 900. The electronic device 900 can be a tablet computer, a notebook computer or a mobile phone. An external connector 910 is plugged into the connector of the electronic device 900. The testing device 100 repeatedly presses the connector 910 from different angles to test the durability of the connector of the electronic device 900.

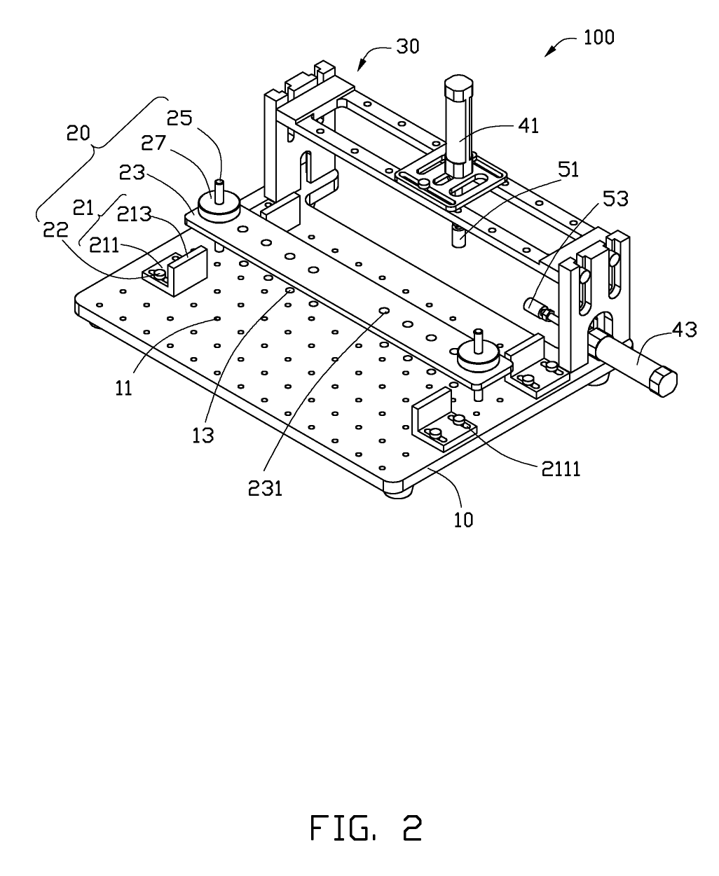

Referring to FIG. 2, an exemplary embodiment of the testing device 100 includes a base 10, a fixing assembly 20, an adjusting assembly 30, a first air cylinder 41, a second air cylinder 43, a first pressing head 51 driven by the first cylinder 41, and a second pressing head 53 driven by the second cylinder 43. The fixing assembly 20 positions the device 900 on the base 10. The adjusting assembly 30 supports the first and second cylinders 41, 43, and respectively adjusts the positions of the cylinders 41, 43 to allow the first head 51 and the second head 53 to align with the connector 910 from two different directions. The first cylinder 41 drives the first head 51 to repeatedly press the connector 910 from one side; the second cylinder 43 drives the second head 53 to repeatedly press the connector 910 from another side.

The base 10 defines a number of threaded holes 11 and a number of fixing holes 13. The fixing assembly 20 includes a number of holding blocks 21, a number of screws 22, a fixing board 23, a number of bolts 25 and corresponding nuts 27. In the exemplary embodiment, the fixing assembly 20 includes two pairs of holding blocks 21, two bolts 25, and two nuts 27. Each pair of the blocks 21 clamps opposite surfaces of the device 900 to hold the device 900 on the testing device 100. In the exemplary embodiment, each block 21 is substantially L-shaped, and includes a fixing portion 211 detachably mounted on the base 10 and a clamping portion 213. Each fixing portion 211 defines two parallel mounting slots 2111. Each screw 32 is located and can move longitudinally in one of the mounting slots 2111, and is screwed in one of the threaded holes 11 to fix the corresponding block 21 on the base 10. The screws 22 can be screwed in different threaded holes 11 to adjust the distance between the two pairs of holding blocks 21 to clamp different size electronic devices.

The fixing board 23 is mounted to the base 10 by the bolts 25 and the nuts 27, and is parallel to the base 10. The fixing board 23 rides on the electronic device 900 to prevent the electronic device 900 from separating from the base 10. A number of mounting holes 231 are defined through the fixing board 23. The two bolts 25 are located at opposite sides of the electronic device 900. One end of each bolt 25 is fixed in one of the fixing holes 13 of the base 10, the other end of each bolt 25 is slidably located in one of the mounting holes 231. Each nut 27 is threadedly engaged with one of the bolts 25, and resists one surface of the fixing board 23 opposite to the base 10. The bolts 25 can selectively be placed in different mounting holes 231 and the corresponding fixing holes 13 to adjust the distance between the two bolts 25, to fix different size electronic devices.

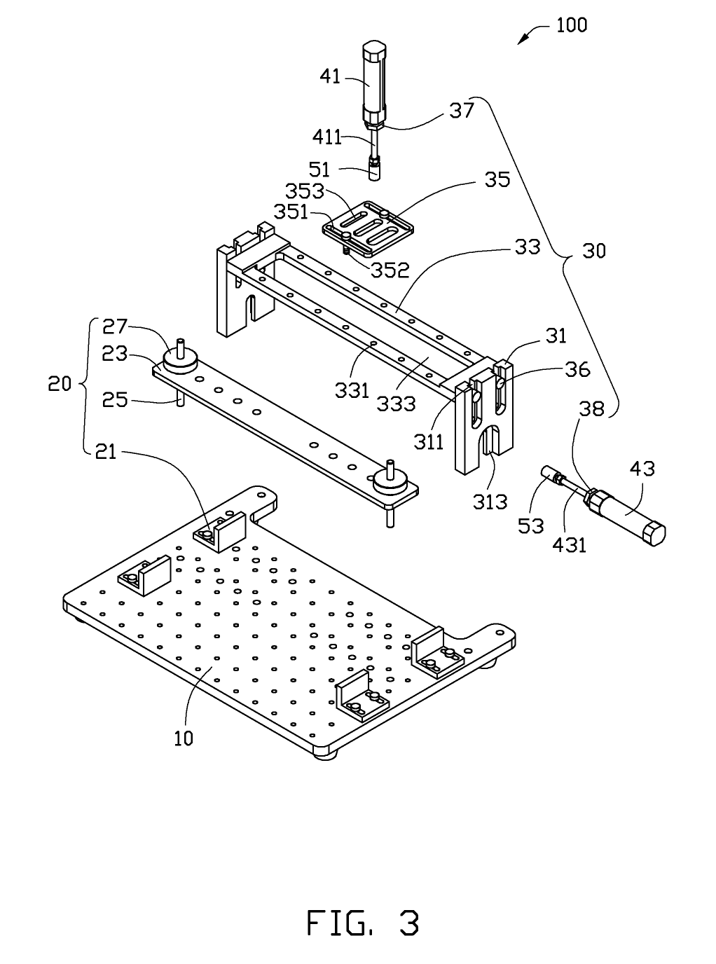

Referring to FIG. 3, the adjusting assembly 30 includes two supporting boards 31 respectively mounted on the two opposite ends of the base 10, a connecting board 33 movably mounted between the two supporting boards 31, and a mounting board 35 movably mounted on the connecting board 33. The first cylinder 41 is movably mounted on the mounting board 35. The first cylinder 41 can be moved along three axes to achieve precise positioning by adjusting the position of the connecting board 33, the mounting board 35, and the first cylinder 41 within at least one fourth slot 353.

In the exemplary embodiment, one end of each supporting board 31 defines two parallel first slots 311, both of which extend along a first direction; the other end of each supporting board 31 defines a second slot 313 extending along the first direction. The adjusting assembly 30 further includes a plurality of mounting screws 36. Each mounting screw 36 is located and can move longitudinally in one of the first slots 311. One end of each mounting screw 36 is attached to the connecting board 33, the other end is bigger than the corresponding first slot 311 to retain the connecting board 33 between the two supporting boards 31. When the mounting screws 36 are loosened, the connecting board 33 can move along the first direction as the mounting screws 36 move in their corresponding first slots 311.

The connecting board 33 defines a slit 333 and a plurality of retaining holes 331 evenly distributed at two opposite sides of the slit 333. The mounting board 35 defines two third slots 351, both of which extend along a second direction perpendicular to the first direction. The two third slots 351 are respectively defined in the two opposite ends of the mounting board 35. The mounting board 35 is fixed on the connecting board 33 by two fasteners 352 which are respectively and movably located in one of the third slots 351. When the two fasteners 352 are loosened, the mounting board 35 can move along the second direction as the two fasteners 352 move in their corresponding third slots 351.

The fourth slot 353, defined between the two third slots 351, extends along a third direction perpendicular to the first direction and the second direction. In the exemplary embodiment, the mounting board 35 has three parallel fourth slots 353. The first cylinder 41 is movably mounted in one of the fourth slots 353. In the exemplary embodiment, the first cylinder 41 includes a first rod 411 movably located in one of the fourth slots 353, the adjusting assembly 30 further includes a first nut 37 threadedly engaged with the first rod 411 and resisting a bottom surface of the mounting board 35. When the first nut 37 is loosened, the first cylinder 41 can move along the third direction as the first rod 411 move in the fourth slot 353.

One end of the first rod 411 passes through the slit 333 of the connecting board 33 and faces the base 10. The first head 51 is fixed on the end of the first rod 411 and aligned with a surface of the external connector 910. Since the connecting board 33 can move relative to the supporting board 31 along the first direction; the mounting board 35 can move relative to the connecting board 33 along the second direction; the first cylinder 41 can move relative to the mounting board 35 along the third direction; and the first direction, the second direction and the third direction are perpendicular to each other, the first cylinder 41 and the first head 51 can be positioned to accommodate different size electronic devices 900.

The second cylinder 43 is movably and detachably mounted on one of the supporting board 31. In the exemplary embodiment, the second cylinder 43 includes a second rod 431 passed through and movably located in one of the second slots 313. The second head 53 is fixed to the end of the second rod 431 and is aligned with another surface of the external connector 910. The adjusting assembly 30 further includes a second nut 38 threadedly engaged with the second rod 431 and resisting an inner surface of the supporting board 31. When the second nut 38 is loosened, the second cylinder 43 can move longitudinally relative to the supporting board 31 as the second rod 431 move in the second slot 313, thus the second head 53 fixed on the second rod 431 can move to align with the external connector 910.

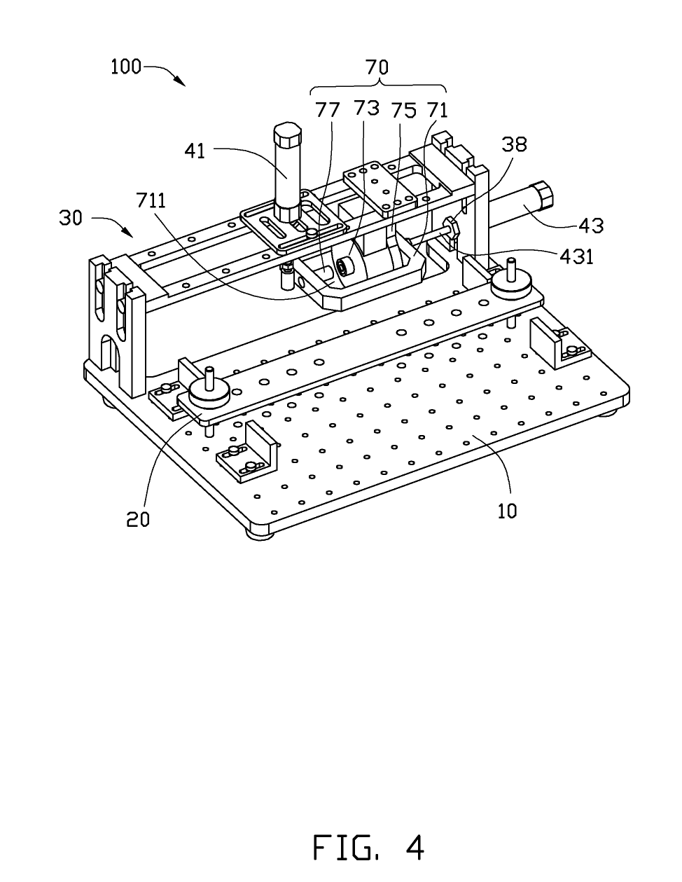

Referring to FIG. 4, the testing device 100 further includes a pressure setting assembly 70 used to set pressure generated by the second cylinder 43. The testing assembly 70 includes a transmission member 71, a load sensor 73, a fixing member 75, and a pressing member 77. The transmission member 71 is mounted to the second rod 431 and a receiving groove 711 is defined through the member 71. The sensor 73, the fixing member 75, and the pressing member 77 are received in the groove 711. One end of the fixing member 75 is fixed to the connecting board 33, and the other end is fixed to the sensor 73. The pressing member 77 is fixed in the groove 711 and aligned with the sensor 73. To set the pressure generated by the second cylinder 43, the second cylinder 43 drives the second rod 431 to move back, the transmission member 71 and the pressing member 77 move with the second cylinder 43 till the pressing member 77 presses the sensor 73, and the sensor 73 senses the pressure from the pressing member 77 and transmits the pressure to a display (not shown), then adjusts the pressure generated by the second cylinder 43 by adjusting a pressure regulator valve (not shown) thereof until a predetermined pressure generated by the second cylinder 43 is reached.

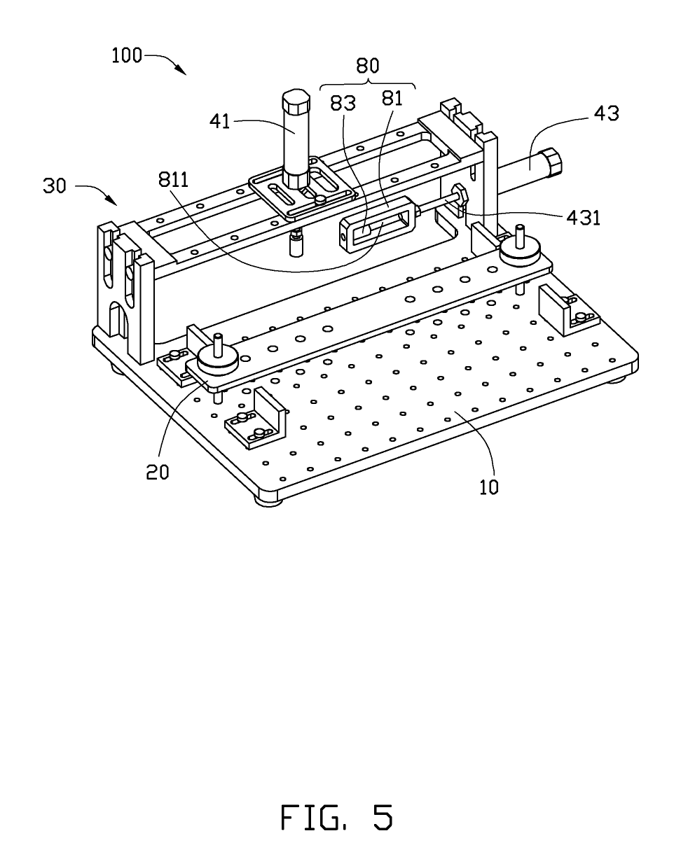

Referring to FIG. 5, the testing device further includes a connecting member 81 and a third pressing head 83. The connecting member 81 is mounted to the second rod 431. A receiving hole 811 defined through the connecting member 81. The third head 83 is received in the receiving hole 811 and fixed on a wall of the receiving hole 811 opposite to the second rod 431. When the testing device 100 tests another type of connector 910 of the electronic device 900, the connector 910 is received in the receiving hole 811 and aligned with the third head 83, the third head 83 presses a surface of the connector 910 opposite to the second rod 431 with the second rod 431 moving back to the second cylinder 43. It is to be understood that the connecting member 81 and the third head 83 can be mounted to the first rod 411 of the first cylinder 41 in the same manner, thus, the first cylinder 41 can drive the third head 83 to press a surface of the connector 910 opposite to the first cylinder 41.

Referring to FIG. 1-3, to test the life of a connector of the electronic device 900, the electronic device 900 is fixed on the base 10 by the holding blocks 21 and the fixing board 23, then adjust the position of the first cylinder 41 to align the first head 51 with a surface of the connector 910, and adjust the position of the second cylinder 43 to align the second head 53 with another surface of the connector 910. The first cylinder 41 and the second cylinder 43 successively and respectively drive the first head 51 and the second head 53 to repeatedly press the connector 910 at a predetermined pressure for a predetermined number of times. Additionally, the electronic device 900 can be reversed to test another two surfaces of the connector if it is desired.

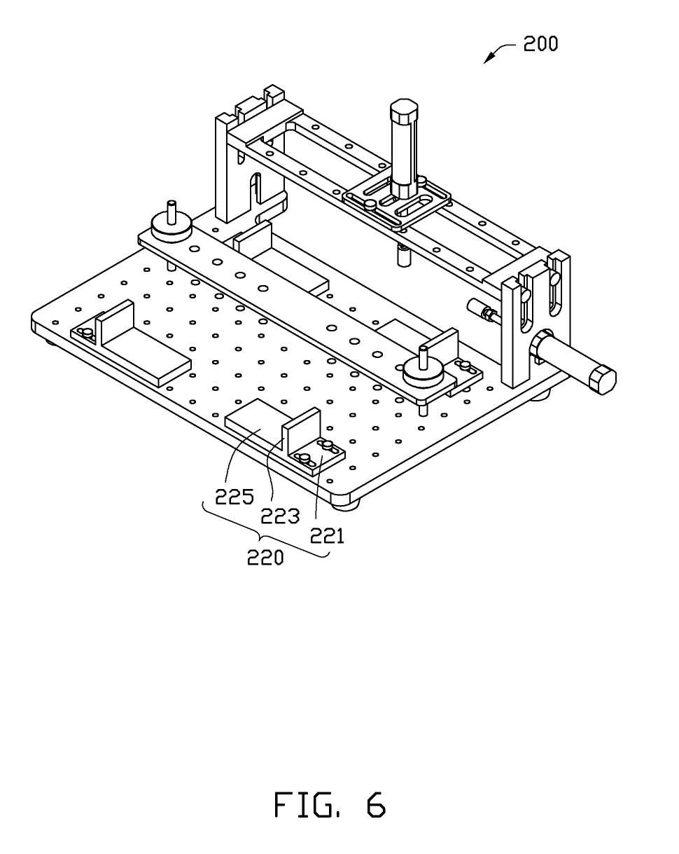

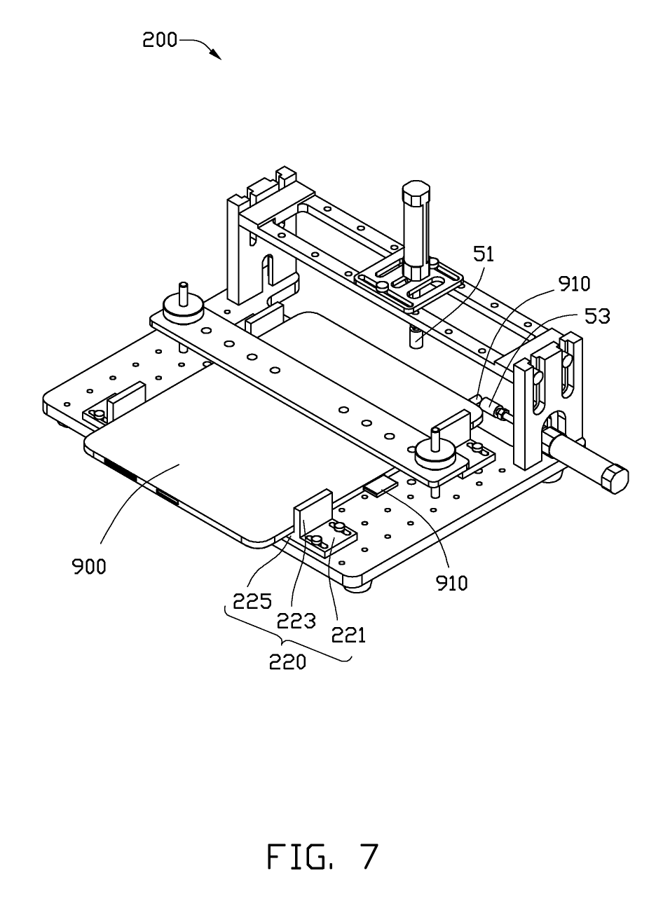

Referring to FIG. 6-7, a connector life testing device 200 according to another exemplary embodiment of the present disclosure is shown. The testing device 200 is similar to the above-described testing device 100, differing in that each holding block 220 of the testing device 200 further includes a raised portion 225 extending from an end of the fixing portion 221 and perpendicular to the resisting porting 223. The raised portion 225 is configured to raise up the electronic device 900 to align the connector 910 with the second head 53.

While reference has been made to the use of air cylinders, that is just one embodiment of a driver that can be used and electro-mechanical servo motors and the like may be used.

It is to be further understood that even though numerous characteristics and advantages of the exemplary embodiments have been set forth in the foregoing description, together with details of structures and functions of various embodiments, the disclosure is illustrative only, and changes may be made in detail, especially in matters of shape, size, and arrangement of parts within the principles of the exemplary invention to the full extent indicated by the broad general meaning of the terms in which the appended claims are expressed.

What is claimed is:

1. A testing device comprising:
a base;
a fixing assembly positioned on the base;
an adjusting assembly comprising two supporting boards respectively mounted on two opposite sides of the base, a connecting board movably mounted between the two supporting boards along the first direction, and a mounting board movably mounted on the supporting board along a second direction perpendicular to the first direction;
a first driver movably mounted on the supporting board along a third direction perpendicular to the first direction and the second direction;
a first pressing head mounted on the first driver, the first pressing head aligning with the external connector by adjusting the position of the connecting board, the mounting board and the first driver.

2. The testing device as claimed in claim 1, wherein the adjusting assembly further comprises a plurality of mounting screws, each supporting board defines at least one first slot extending along the first direction, each mounting screw is located and move longitudinally in one of the first slots, one end of each mounting screw is attached to the connecting board, the other end is bigger than the corresponding first slots to retain the connecting board between the two supporting boards.

3. The testing device as claimed in claim 2, wherein the connecting board defines a plurality of retaining holes, the mounting board defines two third slots, both of which extend along the second direction, the mounting board is mounted on the connecting board by two fasteners which are respectively and movably located in one of the third slots.

4. The testing device as claimed in claim 3, wherein the two third slots are respectively defined through the two opposite ends of the mounting board.

5. The testing device as claimed in claim 3, wherein the mounting board further comprises at least one fourth slot defined between the two third slots and extending along the third direction, the first driver movably mounted in the fourth slot.

6. The testing device as claimed in claim 5, wherein the first driver comprises a first rod, the adjusting assembly further comprises a first nut threadedly engaged with the first rod and resisting a bottom surface of the mounting board.

7. The testing device as claimed in claim 6, wherein the connecting board defines a slit therethrough, the first rod passes through the slit and faces the base, the first pressing head is fixed on the end of the first rod.

8. The testing device as claimed in claim 1, further comprising a second driver and a second pressing head driven by the second driver, wherein one of the supporting board defines a second slot, the second driver movably mounted in the second slot to allow the pressing head align with the external connector.

9. The testing device as claimed in claim 7, wherein the second driver comprises a second rod passed through and movably located in the second slot, the adjusting assembly further comprises a second nut threadedly engaged with the second rod and resisting an inner surface of the supporting board.

10. The testing device as claimed in claim 1, wherein the fixing assembly comprises two pairs of holding blocks, each pairs of the holding blocks clamps opposite surfaces of an electronic device to hold the electronic device on the testing device.

11. The testing device as claimed in claim 10, wherein each holding block includes a fixing portion detachably mounted on the base and a clamping portion clamped to the electronic device, the base defines a plurality of threaded holes, the fixing assembly further comprises a plurality of screws, each fixing portion is fixed on the base by at least one screw screwed in corresponding threaded holes.

12. The testing device as claimed in claim 11, wherein each holding block further comprises a raised portion extending form an end of the fixing portion and perpendicular to the resisting porting, the raised portion is configured to raise up the electronic device.

13. The testing device as claimed in claim 10, wherein the fixing assembly further comprising a fixing board parallel to the base, the fixing board rides on the electronic device to prevent the electronic device from separating form the base.

14. The testing device as claimed in claim 13, wherein the fixing assembly further comprises a plurality of bolts, a plurality of mounting holes defined through the fixing board, one end of each bolt is fixed to the base, the other end is slidably located in one of the mounting holes.

15. The testing device as claimed in claim 8, further comprising a transmission member, a load sensor, a fixing member, and a pressing member, the transmission member is mounted to the second rod, a receiving groove defined through the transmission member, one end of the fixing member is fixed to the connecting board, the other end is fixed to the load sensor, the pressing member is fixed in the receiving groove and aligned with the load sensor, when the second driver drives the second rod to move back, the transmission member and the pressing member move with the second driver till the pressing member presses the load sensor, the load sensor sense the pressure from the pressing member.

16. The testing device as claimed in claim 1, further comprising a connecting member fixed to the first rod and a third pressing head fixed to the connecting member and aligned with the first rod, the third pressing head presses a surface of the external connector opposite to the first rod with the first rod moving back to the first driver.

17. The testing device as claimed in claim 1, further comprising a connecting member fixed to the second rod and a third pressing head fixed to the connecting member and aligned with the second rod, the third pressing head presses a surface of the external connector opposite to the second rod with the first rod moving back to the second driver.
